(19) United States
(12) Patent Application Publication
(10) Pub. No.: US 2026/0142624 A1
(43) Pub. Date: May 21, 2026

(54) RADIO FREQUENCY POWER SUPPLY PROTECTION CIRCUIT AND WIRELESS COMMUNICATION DEVICE

(71) Applicant: SHENZHEN RSPOWER TECHNOLOGY CO., LTD., Shenzhen (CN)

(72) Inventors: Shuxiao WANG, Shenzhen (CN); Yati CHEN, Shenzhen (CN)

(21) Appl. No.: 19/450,008

(22) Filed: Jan. 15, 2026

Related U.S. Application Data
(63) Continuation of application No. PCT/CN2024/108492, filed on Jul. 30, 2024.

(30) Foreign Application Priority Data
Dec. 21, 2023 (CN) 202311763573.5

(51) Int. Cl. H03F 1/52; H03F 1/56

(52) U.S. Cl. CPC H03F 1/52; H03F 1/565; H03F 2200/451; H03F 2200/462; H03F 2200/465; H03F 2200/78

(57) ABSTRACT

A radio frequency (RF) power supply protection circuit and a wireless communication device are provided. The RF power supply protection circuit includes an RF power supply module, a power supply protection module, and an external device. The power supply protection module includes a protection module and a control module. The protection module is connected to the control module. The RF power supply module is connected to the protection module, the control module, and the external device. The RF power supply module is configured to convert an input DC into an RF alternating current signal, and configured to output the RF alternating current signal to the external device. The protection module is configured to output a first comparison result to the control module in response to detecting that an offset angle of a current in the RF power supply module is greater than a preset angle.

This application is a continuation of International Application No. PCT/CN 2024/108492, filed Jul. 30, 2024, which claims priority to Chinese Patent Application No. 202311763573.5, filed Dec. 21, 2023, the entire disclosures of both of which are incorporated herein by reference.

### TECHNICAL FIELD

The disclosure relates to the field of wireless communication network technologies in the internet industry, and in particular, to a radio frequency (RF) power supply protection circuit and a wireless communication device.

### BACKGROUND

Currently, with the increasing demands of the information society, radio frequency (RF) communication, as a communication method for information transmission via radio waves, has been widely used in modern society, such as in radio broadcasting, wireless communication networks, mobile communication, and other fields. In RF communication, RF power supplies are usually used to supply power to network communication devices.

However, during the operation of an RF power supply, reflected power will be generated. If the reflected power is too high, a power supply part may be caused to go into runaway, resulting in damage to a circuit and subsequently affecting the normal operation of the entire system.

### SUMMARY

In a first aspect, an RF power supply protection circuit is provided in the disclosure. The RF power supply protection circuit includes an RF power supply module, a power supply protection module, and an external device. The power supply protection module includes a protection module and a control module. The protection module is connected to the control module. The RF power supply module is connected to the protection module, the control module, and the external device. The RF power supply module is configured to convert an input DC into an RF alternating current signal, and configured to output the RF alternating current signal to the external device. The protection module is configured to output a first comparison result to the control module in response to detecting that an offset angle of a current in the RF power supply module is greater than a preset angle. The control module is configured to perform, in response to reception of the first comparison result, a voltage reduction operation on a DC voltage in the RF power supply module to reduce a reflected power of the RF power supply module.

In a second aspect, a wireless communication device is provided in the disclosure. The wireless communication device includes the RF power supply protection circuit disclosed in the first aspect of the disclosure.

### BRIEF DESCRIPTION OF THE DRAWINGS

In order to describe technical solutions of embodiments of the disclosure more clearly, the following will give a brief introduction to the accompanying drawings used for describing the embodiments or the related art. Apparently, the accompanying drawings hereinafter described are some embodiments of the disclosure. Based on these drawings, those of ordinary skill in the art can also obtain other drawings without creative effort.

FIG. 1 is a schematic diagram of a radio frequency (RF) power supply protection circuit according to embodiments of the disclosure.

FIG. 2 is a structural block diagram of a protection module according to embodiments of the disclosure.

FIG. 3 is a structural block diagram of another protection module according to embodiments of the disclosure.

FIG. 4 is a structural block diagram of an RF power supply module according to embodiments of the disclosure.

FIG. 5 is a structural block diagram of a control module according to embodiments of the disclosure.

FIG. 6 is a structural block diagram of a wireless communication device according to embodiments of the disclosure.

### DETAILED DESCRIPTION

In order to make those skilled in the art understand technical solutions of the disclosure better, the technical solutions of the disclosure are completely and clearly described below with reference to drawings in embodiments of the disclosure. Obviously, the embodiments described are merely some embodiments of the disclosure, and are not all embodiments of the disclosure. All other embodiments obtained by those skilled in the art based on the embodiments in the disclosure without creative effort belong to the protection scope of the disclosure.

Terms such as “first” and “second” in the specification, claims and drawings of the disclosure are used to distinguish different objects, and are not used to describe specific order. In addition, terms “comprise” and “include” and their variations intend to cover non-exclusive inclusion. For example, a process, a method, a system, a product, or a device including a series of operations or units is not limited to listed operations or units, but optionally further includes operations or units that have not been listed, or optionally further includes other operations or units inherent to the process, method, product, or device.

“Embodiment” mentioned herein means that specific features, structures or characteristics described in combination with an embodiment can be included in at least one embodiment of the disclosure. This word appeared at different positions of the specification does not intend to refer to the same embodiment, and does not refer to separate or alternative embodiment exclusive with other embodiments. Those skilled in the art explicitly or implicitly understand that, embodiments described herein can be combined with other embodiments.

The term “and/or” is used to describe an association relationship between associated objects, and indicates that three relationships may exist. For example, “A and/or B” may indicate the following three cases: Only A exists, only B exists, and both A and B exist, where A and B may be singular or plural.

In embodiments of the disclosure, the symbol “/” can indicate that the associated objects are in an “or” relationship. In addition, the symbol “/” may represent a divisor, i.e., perform a division operation. For example, A/B may represent that A is divided by B.

The term “at least one (item) of” or the like in embodiments of the disclosure refers to any combination of these items, including any combination of a single item or multiple items. “At least one (item) of” refers to one or more, and “multiple” refers to two or more than two. For example, at least one (item) of a, b, or c can represent the following seven cases: a; b; c; a and b; a and c; b and c; a, b, and c. Among them, a, b, and c each may be an element or a set including one or more elements.

In embodiments of the disclosure, “equal to” may be used together with “greater than”, and this is applicable to a technical solution used when “greater than” is used; or “equal to” may be used together with “less than”, and this is applicable to a technical solution used when “less than” is used. When “equal to” is used together with “greater than”, “equal to” is not used together with “less than”; or when “equal to” is used together with “less than”, “equal to” is not used together with “greater than”.

Embodiments of the disclosure will be described below with reference to the accompanying drawings.

The technical problem addressed by the disclosure is how to overcome the deficiencies existing in the aforementioned related art. A radio frequency (RF) power supply protection circuit and a wireless communication device are disclosed in the disclosure. By means of detecting an offset angle of the current in an RF power supply module, a direct current (DC) voltage of the RF power supply is limited to keep a reflected power within a preset range, thereby achieving protection of an RF power supply and improving the stability of wireless communication.

Reference is made to FIG. 1, which is a schematic diagram of a radio frequency (RF) power supply protection circuit according to embodiments of the disclosure. As illustrated in FIG. 1, an RF power supply protection circuit 10 includes an RF power supply module 110, a power supply protection module 120, and an external device 130. The power supply protection module 120 includes a protection module 121 and a control module 122. The protection module 121 is connected to the control module 122. The RF power supply module 110 is connected to the protection module 121, the control module 122, and the external device 130. The RF power supply module 110 is configured to convert an input direct current (DC) into an RF alternating current signal, and configured to output the RF alternating current signal to the external device 130. The protection module 121 is configured to output a first comparison result to the control module 122 in response to detecting that an offset angle of a current in the RF power supply module 110 is greater than a preset angle. The control module 122 is configured to perform, in response to reception of the first comparison result, a voltage reduction operation on a DC voltage in the RF power supply module 110 to reduce a reflected power of the RF power supply module 110.

It can be seen that, on the basis of the fundamental RF power supply module 110, in the disclosure, the power supply protection module 120, namely the protection module 121 and the control module 122, is added. The protection module 121 can detect the offset angle of the current in the circuit when the RF power supply module 110 is in an operational state. If the offset angle is greater than the preset angle, it indicates that the transmission power of the circuit in the RF power supply module 110 is too high, which may lead to excessive reflected power. Therefore, further detection is required. The protection module 121 then outputs to the control module 122 a first comparison result indicating that a situation where the offset angle is greater than the preset angle may exist. After receiving the first comparison result, the control module 122 performs a voltage reduction operation on the DC voltage in the RF power supply module 110 to reduce the reflected power, ensuring that the reflected power of the RF power supply module 110 remains within a preset range, thereby achieving the function of protecting the RF power supply.

It can be seen that, in the aforementioned RF power supply protection circuit and the wireless communication device, the protection module 121 and the control module 122 are added to the RF power supply module 110, and the offset angle of the current in the RF power supply module 110 is detected by the protection module 121. When the offset angle is too large, the control module is activated to reduce the DC voltage in the RF power supply module 110, thereby avoiding power supply damage caused by excessive reflected power and improving the stability of wireless communication.

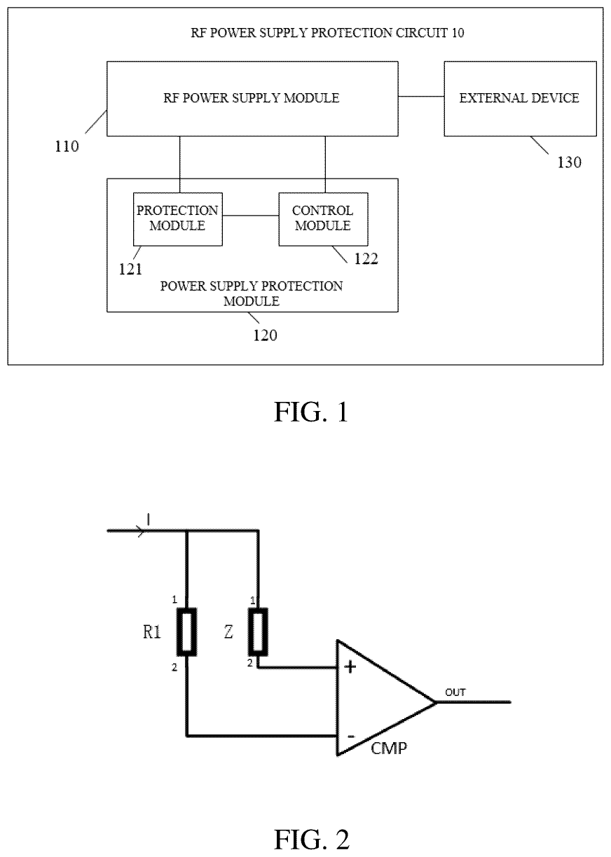

In a possible embodiment, based on the aforementioned schematic diagram of the RF power supply protection circuit, reference is made to FIG. 2, which is a structural block diagram of a protection module according to embodiments of the disclosure. The protection module is the protection module 121 in the aforementioned RF power supply protection circuit 10. The protection module 121 includes a first resistor R1, an impedance element Z, and a comparator CMP. The first resistor R1 and the impedance element Z are connected in parallel. A first end of the first resistor R1 and a first end of the impedance element Z are connected to the RF power supply module 110. A second end of the first resistor R1 is connected to a negative input terminal of the comparator CMP. A second end of the impedance element Z is connected to a positive input terminal of the comparator CMP, and an output terminal of the comparator CMP is connected to the control module 122.

After the current flows from the RF power supply module 110 to the first end (i.e., the input end) of the first resistor R1 and the first end (i.e., the input end) of the impedance element Z, the current flows from the output ends of the first resistor R1 and the impedance element Z to the comparator CMP. The second end of the first resistor R1 is connected to the negative input terminal of the comparator CMP, and the second end of the impedance element Z is connected to the positive input terminal of the comparator CMP. The comparator CMP then outputs the first comparison result to the control module 122 to indicate that the offset angle of the current in two branches is greater than the preset angle.

In a possible embodiment, based on the aforementioned structural block diagram of the protection module 121, the comparator CMP is configured to collect a reference voltage value corresponding to the first resistor R1 and a reference current value corresponding to the impedance element Z, configured to determine the offset angle based on the reference voltage value and the reference current value, and configured to output the first comparison result when the offset angle is greater than the preset angle.

The impedance element refers to an element that has the ability to impede “electricity” (impedance, capacitive reactance, inductive reactance). Therefore, the impedance element Z is a first inductor or a fourth resistor, which is not limited here.

Since the function of the RF power supply is to convert input DC electrical energy into high-frequency alternating current electrical energy, all currents in the protection circuit are alternating currents, and all input voltages are alternating current voltages. Since the first resistor R1 and the impedance element Z are connected in parallel, the alternating current voltage across the first resistor R1 and the alternating current voltage across the impedance element Z are the same. Since the alternating current voltage refers to a voltage whose direction and magnitude change periodically at a certain frequency, the alternating current voltage is specifically calculated according to the following formula: U=Uₒ cos(ωt), where Uₒ represents a peak voltage (or amplitude), ω represents an angular frequency, and t represents time.

Similarly, the current of the first resistor R1 and the current of the impedance element Z are specifically calculated according to the following formula: I=Iₒ cos(ωt+φ), where Iₒ represents a peak current (or amplitude), ω represents an angular frequency, t represents time, and φ represents a phase angle.

The comparator CMP collects a voltage U1 across the first resistor R1 and a current I2 of the impedance element Z, and calculates the phase angle φ based on the aforementioned voltage calculation formula and current calculation formula. The absolute value of the phase angle is the offset angle. If the offset angle is greater than a preset angle φ0, the protection module 121 outputs the first comparison result to the control module 122.

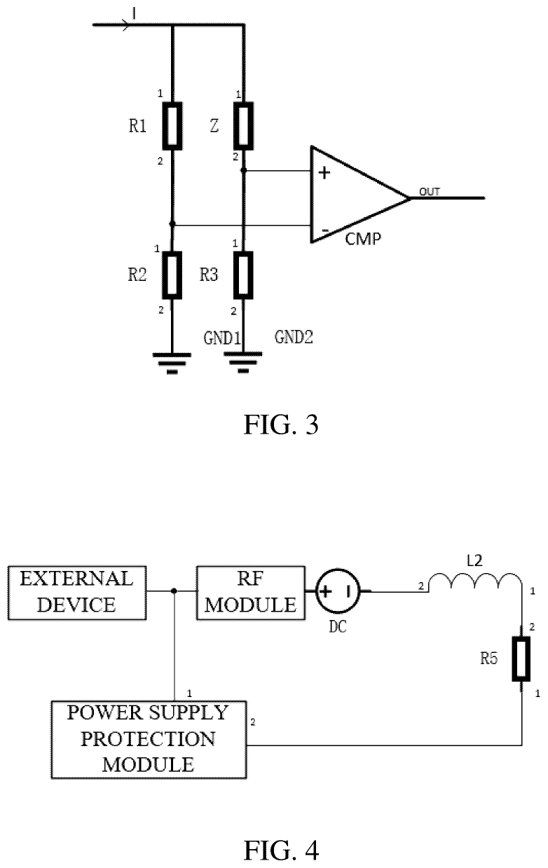

In a possible embodiment, reference is made to FIG. 3, which is a structural block diagram of another protection module according to embodiments of the disclosure. As illustrated in FIG. 3, the protection module 121 further includes a second resistor R2 and a third resistor R3. A first end of the second resistor R2 is connected to both the second end of the first resistor R1 and the negative input terminal of the comparator CMP, and a second end of the second resistor R2 is connected to a ground wire GND1. A first end of the third resistor R3 is connected to both the second end of the impedance element Z and the positive input terminal of the comparator CMP, and a second end of the third resistor R3 is connected to a ground wire GND2.

Grounding refers to an electrical connection method that connects electrical equipment to the ground or earth, which is also an important safety protection measure. The primary purpose of grounding is to ensure the safety of both equipment and personnel, preventing personal injury or equipment failure caused by equipment leakage current or a rise in ground potential.

The second resistor R2 and the third resistor R3 are grounding resistors. Since the resistance of the ground can reach several thousand ohms and the leakage potential is generally a few hundred volts, the resistance value of the grounding resistor is usually very small, generally below 1 ohm. The role of the grounding resistor is not only to ensure the safety of personnel and equipment but also to serve the following purposes. 1. Reduce grounding current: when an equipment experiences a leakage failure, a leakage current is discharged through the grounding wire. If the leakage current is too large, it may pose a risk to personnel and may affect the normal operation of the equipment. The grounding resistor can reduce the magnitude of the grounding current, thereby minimizing harm to personnel and the equipment. 2. Control the rate of rise in ground potential: when the leakage current is discharged through the grounding wire, the ground potential is generated. If the potential rises too rapidly, it may cause an impact on the equipment or even damage the equipment. Grounding resistors can control the rate of rise in ground potential, allowing the ground potential to increase slowly and thus avoiding impact on the equipment. 3. Filtering effect: grounding resistors can provide a certain filtering effect, suppressing high-frequency electromagnetic interference and improving the anti-interference capability of a system.

In a possible embodiment, reference is made to FIG. 4, which is a structural block diagram of an RF power supply module according to embodiments of the disclosure. As illustrated in FIG. 4, the RF power supply module 110 includes an RF module 111, a DC power supply DC, a second inductor L2, and a fifth resistor R5. A positive terminal of the DC power supply DC is connected to a first end of the RF module 111. A second end of the RF module 111 is connected to both a first end of the power supply protection module 120 and an input end of the external device 130. A second end of the power supply protection module 120 is connected to a first end of the fifth resistor R5. A second end of the fifth resistor R5 is connected to a first end of the second inductor L2, and a second end of the second inductor L2 is connected to a negative terminal of the DC power supply DC.

The series connection of the second inductor L2 and the fifth resistor R5 in the circuit serves the following purposes. When a natural response occurs in the circuit, a resistor-inductor (RL) series circuit is well-suited. The inductor's ability to store energy allows the circuit to react to the natural response, and the resistor can make the circuit less sensitive to external interferences. Furthermore, since the function of the RF power supply is to output high-frequency alternating current electrical energy, the RL series circuit can provide faster response and better handle high-frequency interference in such high-frequency conditions. Additionally, the RL series circuit can be used in tuning circuits. With appropriate combinations of inductors and resistors, the RL series circuit can be made responsive to specific frequency ranges.

The RF power supply module 110 is a power supply device used to provide RF signals. The main principle of the RF power supply module 110 illustrated in FIG. 4 is to convert DC electrical energy into an RF alternating current signal and output the RF alternating current signal to a load (i.e., the external device 130). The working principle of the RF power supply can be broadly divided into three steps: DC electrical energy conversion, RF signal generation, and output regulation.

Furthermore, DC electrical energy conversion is a process of converting the input DC electrical energy from a DC power supply into an RF alternating current signal. The DC power supply is configured to convert an input DC electrical energy into a stable DC voltage, and convert it into a high-frequency pulse signal through switching power supply technology. An RF power amplifier in the RF module 111 is configured to amplify the high-frequency pulse signal into the RF alternating current signal. The generation of RF signals relies on an RF oscillator in the RF module 111. As a circuit capable of generating stable RF signals, the RF oscillator typically consists of an oscillator circuit and a feedback circuit. The oscillator circuit is configured to generate the RF signals, while the feedback circuit is configured to feed back a portion of the output signal to the oscillator circuit to maintain oscillation stability. Finally, output regulation is achieved through an output matching network in the RF module 111, and the output matching network is configured to adjust the RF signals for compatibility with the load (i.e., the external device 130). The output matching network is configured to adjust the impedance of the output signal to match the impedance of the load.

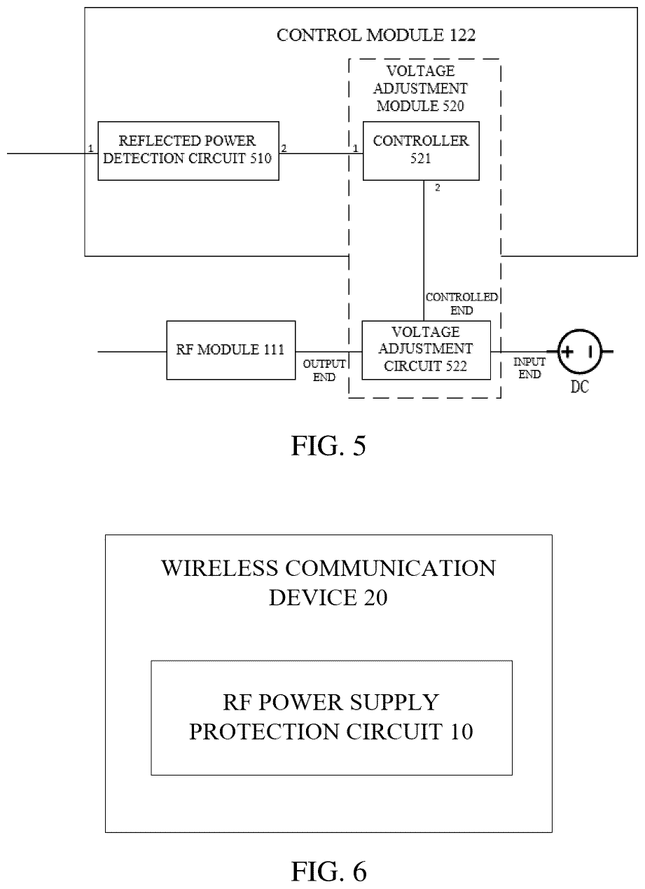

In a possible embodiment, reference is made to FIG. 5, which is a structural block diagram of a control module according to embodiments of the disclosure. As illustrated in FIG. 5, the control module 122 includes a reflected power detection circuit 510 and a voltage adjustment module 520. The voltage adjustment module 520 includes a controller 521 and a voltage adjustment circuit 522. A first end of the reflected power detection circuit 510 is connected to the protection module 121. A second end of the reflected power detection circuit 510 is connected to a first end of the controller 521. A second end of the controller 521 is connected to a controlled end of the voltage adjustment circuit 522. An input end of the voltage adjustment circuit 522 is connected to the positive terminal of the DC power supply, and an output end of the voltage adjustment circuit 522 is connected to the first end of the RF module 111.

In a possible embodiment, based on the aforementioned structural block diagram of the control module 122, the reflected power detection circuit 510 is configured to detect a reflected power of the RF power supply module 110. The controller 521 is configured to determine, in response to the first comparison result, a power difference value based on the reflected power and a preset power, configured to determine a voltage drop value based on the power difference value, and configured to output a control instruction based on the voltage drop value. The voltage adjustment circuit 522 is configured to adjust, in response to the control instruction, the DC voltage based on the voltage drop value and a current voltage value.

After the control module 122 receives the first comparison result sent by the protection module 121, a portion by which the reflected power exceeds the preset range is determined. Based on this, a required voltage drop value is determined. Then the input DC voltage in the RF power supply module 110 is reduced by the voltage adjustment circuit 522 in response to the output control instruction.

In a possible embodiment, the protection module 121 is configured to, in response to detecting that the offset angle of the current is less than or equal to the preset angle, output a second comparison result to the control module 122. The control module 122 is configured to skip output of the control instruction in response to reception of the second comparison result sent by the protection module 121.

When the offset angle of the alternating current in the RF power supply module 110 is relatively small, i.e., less than or equal to the preset angle, it indicates that the RF transmission power of the circuit is not very high, meaning there is no need to perform a voltage reduction operation on the input DC voltage in the RF power supply module 110. Therefore, after receiving the second comparison result, the control module 122 does not need to output the control instruction.

It can be seen that, in the RF power supply protection circuit 10 provided in any of the aforementioned embodiments of the disclosure, by means of detecting the offset angle of the current, the DC voltage of the RF power supply is limited, thereby keeping the reflected power within a preset range, such that the RF power supply is protected and the stability of wireless communication is improved.

In a possible embodiment, reference is made to FIG. 6, a wireless communication device 20 is provided in the disclosure. The wireless communication device 20 includes the RF power supply protection circuit 10 provided in any of the above embodiments of the disclosure.

The RF power supply protection circuit 10 in the wireless communication device 20 is the same as the RF power supply protection circuit 10 described in any of the aforementioned embodiments of the disclosure, which will not be repeated here. It may be noted that, for simplicity of description, the above embodiments are described in a form of a combination of a series of operations. However, those skilled in the art can understand clearly that, the disclosure is not limited by the order of the operations, since some operations may be performed simultaneously or in other orders according to the disclosure. In addition, those skilled in the art can understand clearly that, the described embodiments are preferred embodiments, of which relative operations or modules may not be necessary for the disclosure.

In above embodiments, each embodiment may be described with focusing on different aspects. Parts not be described in some embodiments may refer to relative descriptions in other embodiments.

It should be understood that, the apparatus disclosed in several embodiments provided by the disclosure can be realized in any other manner. For example, the apparatus embodiments described above can be merely exemplary, for example, the units are just divided according to logic functions. In practical implementation, the units can be divided in other manners, for example, multiple units or components can be combined or integrated into another system, or some features can be omitted or not executed. In addition, the mutual coupling or direct coupling or communication connection described or discussed can be via some interfaces, and indirect coupling or communication connection between devices or units may be electrical, mechanical or of other forms.

The units illustrated as separate components can be or not be separated physically, and components described as units can be or not be physical units, i.e., can be located at one place, or can be distributed onto multiple network units. It is possible to select some or all of the units according to actual needs, for realizing the objective of embodiments of the disclosure.

In addition, respective functional units in respective embodiments of the disclosure can be integrated into one processing unit, or can be present as separate physical entities. It is also possible that two or more than two units are integrated into one unit. The integrated units may be implemented in form of hardware, or in form of functional software units.

The above embodiments in the disclosure are described in detail. Principles and implementation manners of the disclosure are elaborated with specific embodiments herein. The above illustration of embodiments is only used to help to understand methods and core ideas of the disclosure. At the same time, for those of ordinary skill in the art, according to ideas of the disclosure, there will be changes in specific implementation manners and application scope. In conclusion, contents of this specification should not be understood as limitations on the disclosure.

What is claimed is:

1. A radio frequency (RF) power supply protection circuit, comprising: an RF power supply module, a power supply protection module, and an external device; wherein
the power supply protection module comprises a protection module and a control module, wherein the protection module is connected to the control module; and the RF power supply module is connected to the protection module, the control module, and the external device;
the RF power supply module is configured to convert an input direct current (DC) into an RF alternating current signal, and configured to output the RF alternating current signal to the external device;
the protection module is configured to output a first comparison result to the control module in response to detecting that an offset angle of a current in the RF power supply module is greater than a preset angle; and
the control module is configured to perform, in response to reception of the first comparison result, a voltage reduction operation on a DC voltage in the RF power supply module to reduce a reflected power of the RF power supply module.

2. The RF power supply protection circuit according to claim 1, wherein the protection module comprises a first resistor, an impedance element, and a comparator;
the first resistor and the impedance element are connected in parallel, a first end of the first resistor and a first end of the impedance element are connected to the RF power supply module, a second end of the first resistor is connected to a negative input terminal of the comparator, a second end of the impedance element is connected to a positive input terminal of the comparator, and an output terminal of the comparator is connected to the control module.

3. The RF power supply protection circuit according to claim 2, wherein the comparator is configured to collect a reference voltage value corresponding to the first resistor and a reference current value corresponding to the impedance element, configured to determine the offset angle based on the reference voltage value and the reference current value, and configured to output the first comparison result when the offset angle is greater than the preset angle.

4. The RF power supply protection circuit according to claim 2, wherein the protection module further comprises a second resistor and a third resistor;
a first end of the second resistor is connected to both the second end of the first resistor and the negative input terminal of the comparator, and a second end of the second resistor is connected to a ground wire; and
a first end of the third resistor is connected to both the second end of the impedance element and the positive input terminal of the comparator, and a second end of the third resistor is connected to the ground wire.

5. The RF power supply protection circuit according to claim 2, wherein the impedance element is a first inductor or a fourth resistor.

6. The RF power supply protection circuit according to claim 1, wherein the RF power supply module comprises an RF module, a DC power supply, a second inductor, and a fifth resistor;
a positive terminal of the DC power supply is connected to a first end of the RF module, a second end of the RF module is connected to both a first end of the power supply protection module and an input end of the external device, a second end of the power supply protection module is connected to a first end of the fifth resistor, a second end of the fifth resistor is connected to a first end of the second inductor, and a second end of the second inductor is connected to a negative terminal of the DC power supply.

7. The RF power supply protection circuit according to claim 6, wherein the control module comprises a reflected power detection circuit and a voltage adjustment module;
the voltage adjustment module comprises a controller and a voltage adjustment circuit; and
a first end of the reflected power detection circuit is connected to the protection module, a second end of the reflected power detection circuit is connected to a first end of the controller, a second end of the controller is connected to a controlled end of the voltage adjustment circuit, an input end of the voltage adjustment circuit is connected to the positive terminal of the DC power supply, and an output end of the voltage adjustment circuit is connected to the first end of the RF module.

8. The RF power supply protection circuit according to claim 7, wherein the reflected power detection circuit is configured to detect a reflected power of the RF power supply module;
the controller is configured to determine, in response to the first comparison result, a power difference value based on the reflected power and a preset power, configured to determine a voltage drop value based on the power difference value, and configured to output a control instruction based on the voltage drop value; and
the voltage adjustment circuit is configured to adjust, in response to the control instruction, the DC voltage based on the voltage drop value and a current voltage value.

9. The RF power supply protection circuit according to claim 8, wherein the protection module is configured to, in response to detecting that the offset angle of the current is less than or equal to the preset angle, output a second comparison result to the control module; and
the control module is configured to skip output of the control instruction in response to reception of the second comparison result sent by the protection module.

10. A wireless communication device, comprising a radio frequency (RF) power supply protection circuit, wherein the RF power supply protection circuit comprises an RF power supply module, a power supply protection module, and an external device; wherein
the power supply protection module comprises a protection module and a control module, wherein the protection module is connected to the control module; and the RF power supply module is connected to the protection module, the control module, and the external device;
the RF power supply module is configured to convert an input direct current (DC) into an RF alternating current signal, and configured to output the RF alternating current signal to the external device;
the protection module is configured to output a first comparison result to the control module in response to detecting that an offset angle of a current in the RF power supply module is greater than a preset angle; and
the control module is configured to perform, in response to reception of the first comparison result, a voltage reduction operation on a DC voltage in the RF power supply module to reduce a reflected power of the RF power supply module.

11. The wireless communication device according to claim 10, wherein the protection module comprises a first resistor, an impedance element, and a comparator;
the first resistor and the impedance element are connected in parallel, a first end of the first resistor and a first end of the impedance element are connected to the RF power supply module, a second end of the first resistor is connected to a negative input terminal of the comparator, a second end of the impedance element is connected to a positive input terminal of the comparator, and an output terminal of the comparator is connected to the control module.

12. The wireless communication device according to claim 11, wherein the comparator is configured to collect a reference voltage value corresponding to the first resistor and a reference current value corresponding to the impedance element, configured to determine the offset angle based on the reference voltage value and the reference current value, and configured to output the first comparison result when the offset angle is greater than the preset angle.

13. The wireless communication device according to claim 11, wherein the protection module further comprises a second resistor and a third resistor;
a first end of the second resistor is connected to both the second end of the first resistor and the negative input terminal of the comparator, and a second end of the second resistor is connected to a ground wire; and
a first end of the third resistor is connected to both the second end of the impedance element and the positive input terminal of the comparator, and a second end of the third resistor is connected to the ground wire.

14. The wireless communication device according to claim 11, wherein the impedance element is a first inductor or a fourth resistor.

15. The wireless communication device according to claim 10, wherein the RF power supply module comprises an RF module, a DC power supply, a second inductor, and a fifth resistor;
a positive terminal of the DC power supply is connected to a first end of the RF module, a second end of the RF module is connected to both a first end of the power supply protection module and an input end of the external device, a second end of the power supply protection module is connected to a first end of the fifth resistor, a second end of the fifth resistor is connected to a first end of the second inductor, and a second end of the second inductor is connected to a negative terminal of the DC power supply.

16. The wireless communication device according to claim 15, wherein the control module comprises a reflected power detection circuit and a voltage adjustment module;
the voltage adjustment module comprises a controller and a voltage adjustment circuit; and
a first end of the reflected power detection circuit is connected to the protection module, a second end of the reflected power detection circuit is connected to a first end of the controller, a second end of the controller is connected to a controlled end of the voltage adjustment circuit, an input end of the voltage adjustment circuit is connected to the positive terminal of the DC power supply, and an output end of the voltage adjustment circuit is connected to the first end of the RF module.

17. The wireless communication device according to claim 16, wherein the reflected power detection circuit is configured to detect a reflected power of the RF power supply module;
the controller is configured to determine, in response to the first comparison result, a power difference value based on the reflected power and a preset power, configured to determine a voltage drop value based on the power difference value, and configured to output a control instruction based on the voltage drop value; and
the voltage adjustment circuit is configured to adjust, in response to the control instruction, the DC voltage based on the voltage drop value and a current voltage value.

18. The wireless communication device according to claim 17, wherein the protection module is configured to, in response to detecting that the offset angle of the current is less than or equal to the preset angle, output a second comparison result to the control module; and
the control module is configured to skip output of the control instruction in response to reception of the second comparison result sent by the protection module.
